(19) United States
(12) Patent Application Publication
(10) Pub. No.: US 2025/0048911 A1
(43) Pub. Date: Feb. 6, 2025

(54) LIGHT-EMITTING DEVICE PREPARATION METHOD, LIGHT-EMITTING DEVICE, AND DISPLAY APPARATUS

(71) Applicant: TCL TECHNOLOGY GROUP CORPORATION, Huizhou, Guangdong (CN)

(72) Inventors: Zitong AO, Huizhou, Guangdong (CN); Jianxin ZHANG, Huizhou, Guangdong (CN); Yiran YAN, Huizhou, Guangdong (CN); Jiating HONG, Huizhou, Guangdong (CN); Fan YANG, Huizhou, Guangdong (CN); Xindi MO, Huizhou, Guangdong (CN)

(73) Assignee: TCL TECHNOLOGY GROUP CORPORATION, Huizhou, Guangdong (CN)

(21) Appl. No.: 18/706,759

(22) PCT Filed: Nov. 1, 2022
(86) PCT No.: PCT/CN2022/128927

§ 371 Date: May 2, 2024

(30) Foreign Application Priority Data
Nov. 3, 2021 (CN) 202111294610.3

(51) Int. Cl. H10K 71/40; H10K 71/15

(52) U.S. Cl. CPC H10K 71/40; H10K 71/15

(57) ABSTRACT

A light-emitting device preparation method includes: preparing one or more functional layers on a first electrode; preparing a second electrode on the one or more functional layers; wherein, at least one of the one or more functional layers is obtained by subjecting a solution of the corresponding functional layer material to a first thermal annealing treatment and then a second thermal annealing treatment.

### CROSS-REFERENCE TO RELATED APPLICATIONS

This present disclosure claims priority to Chinese Patent Application No. 202111294610.3, filed in the China National Intellectual Property Administration on Nov. 3, 2021, and entitled “LIGHT-EMITTING DEVICE PREPARATION METHOD, LIGHT-EMITTING DEVICE, AND DISPLAY APPARATUS”, the disclosure of which is incorporated herein by reference in its entirety.

### TECHNICAL FIELD

The present disclosure relates to the field of display technologies, and in particular, to a light-emitting device preparation method, a light-emitting device, and a display apparatus.

### BACKGROUND

Electroluminescence, also known as electric field luminescence, is a physical phenomenon that electrons excited by the electric field impact the luminescence center through the voltage applied to two electrodes, resulting in the transition, change, and recombination of electrons between energy levels, resulting in luminescence. Light-emitting devices can be divided into quantum dot light-emitting devices (QLED) and organic light-emitting devices (OLED) according to the different materials of the light-emitting layers.

However, there are still many problems in the research and development of light-emitting devices. In experimental development or industrial production, spin-coating process or inkjet printing process is commonly configured to preparing light-emitting devices, but in the process of preparing functional layers with solution, functional layers often crack, which is caused by internal stress in the functional layers. The so-called internal stress refers to the stress that still remains inside the object after the external load is removed. It is caused by uneven volume changes in the macroscopic or microstructure structure of the material. When there is no external force, the stress stored in an elastic object is called internal stress. Its characteristic is to form a balanced force system in the object, that is, to obey the static conditions. According to the nature and range, it can be divided into macro stress, micro stress and ultra-micro stress. According to the cause, it can be divided into thermal stress and tissue stress. According to the existence time, it can be divided into instant stress and residual stress. According to the direction of action, it can be divided into longitudinal stress and lateral stress.

### Technical Problems

The optoelectronic performance of existing light-emitting devices needs to be improved.

### SUMMARY

Therefore, the present disclosure provides a light-emitting device preparation method, a light-emitting device, and a display apparatus.

An embodiment of the present disclosure provides a method of preparing a light-emitting device, the method includes:
preparing one or more functional layers on a first electrode; and
preparing a second electrode on the one or more functional layers;
wherein, at least one of the one or more functional layers are obtained by subjecting a solution of a material of a corresponding functional layer material to a first thermal annealing treatment and then a second thermal annealing treatment.

Alternatively, in some embodiments of the present disclosure, in the second thermal annealing treatment, a thermal annealing temperature of the second thermal annealing treatment ranges from 60° C. to 120° C.

Alternatively, in some embodiments of the present disclosure, in the second thermal annealing treatment, a thermal annealing time of the second thermal annealing treatment ranges from 5 min to 10 min.

Alternatively, in some embodiments of the present disclosure, after the second thermal annealing treatment, a functional layer is cooled with a first solvent by coating or soaking, and then a next layer is disposed.

Alternatively, in some embodiments of the present disclosure, a polarity of the first solvent is less than a polarity of a solvent in a solution of a material each of functional layers.

Alternatively, in some embodiments of the present disclosure, the first solvent is a non-polar solvent.

Alternatively, in some embodiments of the present disclosure, the solvent in the solution of the material of each of functional layers is orthogonal, and the polarity of the first solvent is the same as that of the solvent in the solution of the material of a next functional layer to be disposed.

Alternatively, in some embodiments of the present disclosure, a temperature of the first solvent is less than or equal to 15° C.

Alternatively, in some embodiments of the present disclosure, the one or more functional layers include a light-emitting layer, a hole injection layer, a hole transport layer and an electron transport layer, the hole injection layer and the hole transport layer are disposed between the light-emitting layer and the first electrode, the hole injection layer is disposed close to the first electrode, the hole transport layer is disposed close to the second electrode, and the electron transport layer is disposed between the light-emitting layer and the second electrode, wherein one or more layers of the hole injection layer, the hole transport layer, the light-emitting layer and the electron transport layer are processed by the second thermal annealing treatment.

Alternatively, in some embodiments of the present disclosure, the method includes:
disposing the solution of the material of a hole injection layer on the first electrode, performing the first thermal annealing treatment and the second thermal annealing treatment to form the hole injection layer;
disposing the solution of the material of a hole transport layer on the hole injection layer, performing the first thermal annealing treatment and the second thermal annealing treatment to form the hole transport layer;
disposing the solution of the material of a light-emitting layer on the hole transport layer, performing the first thermal annealing treatment and the second thermal annealing treatment to form the light-emitting layer;
disposing the solution of the material of a electron transport layer on the light-emitting layer, performing the first thermal annealing treatment and the second thermal annealing treatment to form the electron transport layer; and
preparing the second electrode on the electron transport layer.

Alternatively, in some embodiments of the present disclosure, the method includes:
disposing the solution of the material of the electron transport layer on the first electrode, performing the first thermal annealing treatment and the second thermal annealing treatment to form the electron transport layer;
disposing the solution of the material of the light-emitting layer on the electron transport layer, performing the first thermal annealing treatment and the second thermal annealing treatment to form the light-emitting layer;
disposing the solution of the material of the hole transport layer on the light-emitting layer, performing the first thermal annealing treatment and the second thermal annealing treatment to form the hole transport layer;
disposing the solution of the material of the hole injection layer on the hole transport layer, performing the first thermal annealing treatment and the second thermal annealing treatment to form the hole injection layer; and
preparing the second electrode on the hole injection layer.

Alternatively, in some embodiments of the present disclosure, in the second thermal annealing treatment, the functional layer is cooled with the first solvent by coating or soaking, and then the next layer is disposed; wherein a solvent contained in the solution of the material of the hole injection layer is a second solvent, a solvent contained in the solution of the material of the hole transport layer is a third solvent, a solvent contained in the solution of the material of the light-emitting layer is a fourth solvent, a solvent contained in the solution of the material of the electron transport layer is a fifth solvent, a polarity of the second solvent is greater than or equal to a polarity of the third solvent, the polarity of the third solvent is greater than or equal to a polarity of the fourth solvent, and the polarity of the fourth solvent is greater than or equal to a polarity of the fifth solvent;
wherein the polarity of the first solvent is less than the polarity of the fifth solvent.

Alternatively, in some embodiments of the present disclosure, in the second thermal annealing treatment, the functional layer is cooled with the first solvent by coating or soaking, and then the next layer is disposed; wherein the solvent contained in the solution of the material of the hole injection layer is the second solvent, the solvent contained in the solution of the material of the hole transport layer is the third solvent, the solvent contained in the solution of the material of the light-emitting layer is the fourth solvent, the solvent contained in the solution of the material of the electron transport layer is the fifth solvent, a polarity of the second solvent is greater than or equal to a polarity of the third solvent, the polarity of the third solvent is greater than or equal to a polarity of the fourth solvent, and the polarity of the fourth solvent is greater than or equal to a polarity of the fifth solvent; wherein the first solvent is the non-polar solvent.

Alternatively, in some embodiments of the present disclosure, in the second thermal annealing treatment, the functional layer is cooled with the first solvent by coating or soaking, and then the next layer is disposed; wherein the solvent contained in the solution of the material of the hole injection layer is the second solvent, the solvent contained in the solution of the material of the hole transport layer is the third solvent, the solvent contained in the solution of the material of the light-emitting layer is the fourth solvent, the solvent contained in the solution of the material of the electron transport layer is the fifth solvent, a polarity of the second solvent is greater than or equal to a polarity of the third solvent, the polarity of the third solvent is greater than or equal to a polarity of the fourth solvent, and the polarity of the fourth solvent is greater than or equal to a polarity of the fifth solvent;
wherein in the second thermal annealing treatment of the hole injection layer, the first solvent is same as the third solvent; and in the second thermal annealing treatment of the hole transport layer, the first solvent is same as the fourth solvent; and in the second thermal annealing treatment of the light-emitting layer, the first solvent is same as the fifth solvent.

Alternatively, in some embodiments of the present disclosure, the temperature of the first solvent is less than or equal to 15° C.

Alternatively, in some embodiments of the present disclosure, a thermal annealing temperature of the first thermal annealing treatment ranges from 60° C. to 120° C.

Alternatively, in some embodiments of the present disclosure, a thermal annealing time of the first thermal annealing treatment ranges from 10 min to 30 min.

Alternatively, in some embodiments of the present disclosure, the material of the light-emitting layer includes a direct bandgap compound semiconductor or a perovskite type semiconductor, the direct bandgap compound semiconductor includes one or more of a group II-VI compound, a group III-V compound, a group II-V compound, a group III-VI compound, a group IV-VI compound, a group I-III-VI compound, a group II-IV-VI compound, and a group IV elementary substance, the group II-VI compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, and CdZnSTe; the group III-V compound is selected from one or more of InP, InAs, GaP, GaAs, GaSb, AlN, AlP, InAsP, InNP, InNSb, GaAlNP, and InAlNP; the group I-III-VI compound is selected from one or more of CuInS₂, CuInSe₂, and AgInS₂; the perovskite type semiconductor includes one or more of a doped inorganic perovskite type semiconductors, a undoped inorganic perovskite type semiconductors, and an organic-inorganic hybrid perovskite type semiconductor, a general structure formula of the inorganic perovskite type semiconductors is AMX₃, a general structure formula of the organic-inorganic hybrid perovskite type semiconductor is BMX₃, wherein A is C_{S}⁺, B is an organic amine cation, the organic amine cation includes CH₃(CH₂)ₙ₋₂NH₃⁺ (n≥2) or NH₃⁺ (CH₂)ₙNH₃²⁺ (n≥2), M is a divalent metal cation, the divalent metal cation includes one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion, the halogen anion includes one of Cl⁻, Br⁻, and I⁻;
the material of the hole injection layer includes one or more of PEDOT:PSS, CuPc, F4-TCNQ, HATCN, a transition metal oxide, and a transition metal chalcogenides;
the material of the hole transport layer includes one or more of poly(9,9-dioctylfluorene-co-N-(4-butylphenyl)diphenylamine), poly(N-vinylcarbazole), poly[N,N′-bis(4-butylphenyl)-N,N′-bisphenylbenzidine],Poly[(9,9-dioctylfluorenyl-2, 7-diyl)-co-(N,N′-diphenyl)-N,N′di(p-butyl-oxy-phenyl)-1,4-diaMinobenzene), 4,4′,4″-Tris(carbazol-9-yl)-triphenylamine, 4,4′-Di(9H-carbazol-9-yl)-1,1′-biphenyl, N,N′-bis(3-methylphenyl)-N,N′-diphenyl-benzidine, N,N′-Bis(1-naphthalenyl)-N,N′-bisphenyl-(1,1′-biphenyl)-4,4′-diamine, graphene, and C60; and
the material of the electron transport layer includes one or more of ZnO, TiO₂, SnO₂, Ta₂O₃, ZrO₂, NiO, TiLiO, ZnAlO, ZnMgO, ZnSnO, ZnLiO, and InSnO.

Correspondingly, an embodiment of the present disclosure further provides the light-emitting device prepared by the above method.

Correspondingly, an embodiment of the present disclosure further provides the display device including the above-mentioned light-emitting device.

### Advantageous Effects

In the present disclosure, internal stress of a functional layer is removed by means of performing thermal annealing treatment on the functional layer of the light-emitting device twice, thereby alleviating the problem of a functional layer being prone to cracking, and improving the yield and photoelectric performance of the light-emitting device.

### BRIEF DESCRIPTION OF THE DRAWINGS

In order to illustrate the technical solutions of the present disclosure clearly, the following will briefly describe the accompanying drawings involved in the description of embodiments. It will be apparent that the drawings in the following description are merely some of the embodiments of the present disclosure, and other drawings may be obtained by those skilled in the art without involving any inventive effort based on these drawings.

FIG. 1 is a flowchart of a light-emitting device preparation method according to a first embodiment of the present disclosure.

FIG. 2 is a flowchart of the light-emitting device preparation method according to a second embodiment of the present disclosure.

FIG. 3 is a flowchart of the light-emitting device preparation method according to a third embodiment of the present disclosure.

FIG. 4 is a schematic structural diagram of the light-emitting device according to an embodiment of the present disclosure.

FIG. 5 is a schematic structural diagram of the light-emitting device according to another embodiment of the present disclosure.

FIG. 6 is a photograph of a topography of each of light-emitting devices according to an embodiment of the present disclosure.

EMBODIMENTS OF THE PRESENT DISCLOSURE

The technical solutions in the present disclosure will be fully and clearly described with reference to the accompanying drawings. It is apparent that the described embodiments are only a part of the embodiments of the present disclosure, rather than all of the embodiments. Based on the embodiments in the present disclosure, all other embodiments obtained by a person skilled in the art without involving any inventive effort fall within the scope of the present disclosure.

Detailed instructions are given below. It should be noted that the order of description of the following embodiments is not intended as a limitation of the preferred order of the embodiments. In addition, in the description of the present disclosure, the term “includes” means “includes but is not limited to”.

Various embodiments of the present disclosure may exist in the form of a range. It should be understood that the description in range format is merely for convenience and brevity, and should not be construed as a rigid restrictions on the scope of the present disclosure. Therefore, it should be considered that the range description has specifically disclosed all possible sub-ranges as well as a single value within the range. For example, it should be considered that the range description from 1 to 6 has specifically disclosed sub-ranges, such as from 1 to 3, from 1 to 4, from 1 to 5, from 2 to 4, from 2 to 6, from 3 to 6, and the like, and single numbers within the ranges, such as 1, 2, 3, 4, 5, and 6, which apply regardless of the range. In addition, whenever a numeric range is indicated herein, it includes any referenced number (fraction or integer) within the referenced range.

In the present disclosure, “one or more layers” refers to one or more, and “more” refers to two or more. “One or more”, “at least one of the following” or similar expressions refer to any combination of these items, including any combination of single items (items) or complex items (items). For example, “at least one of a, b, or c”, or “at least one of a, b, and c”, mean: a, b, c, a-b (i.e. a and b), a-c, b-c, or a-b-c, among them, a, b, c may be single or multiple, respectively.

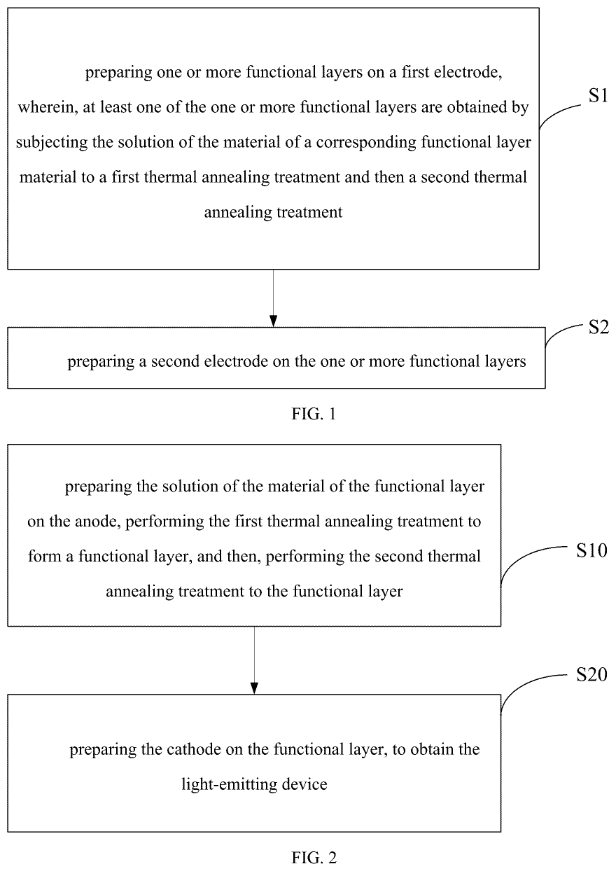

Referring to FIG. 1, an embodiment of the present disclosure provides a light-emitting device preparation method, wherein the preparation method includes:
S1: preparing one or more functional layers on a first electrode, wherein, at least one of the one or more functional layers are obtained by subjecting the solution of the material of a corresponding functional layer material to a first thermal annealing treatment and then a second thermal annealing treatment; and
S2: preparing a second electrode on the one or more functional layers.

In an embodiment of the present disclosure, the light-emitting device may be a light-emitting device having a positive structure or an inverted structure. According to the difference in structure, the first electrode may be a cathode or an anode, and correspondingly, the second electrode may be the anode or the cathode.

Further, it will be appreciated that in some embodiments, the number of the functional layers is one layer or more, for example, two layers, three layers, four layers or more, and the type of a material of each of functional layers is the same or different.

As shown in FIG. 2, FIG. 2 provides the method of preparing a light-emitting device having the positive structure. In the light-emitting device having the positive structure, the first electrode is the anode, and the second electrode is the cathode. The light-emitting device having the positive structure includes the anode, a functional layer and the cathode from bottom to top. The specific steps of the preparation method which an embodiment of the present disclosure provided, including:
S10: preparing the solution of the material of the functional layer on the anode, performing the first thermal annealing treatment to form a functional layer, and then, performing the second thermal annealing treatment to the functional layer; and
S20: preparing the cathode on the functional layer, to obtain the light-emitting device.

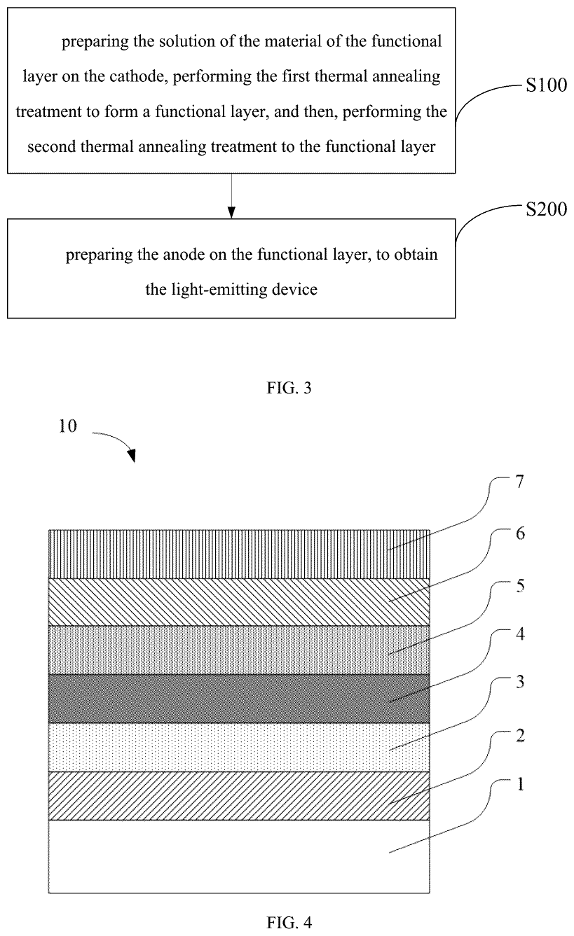

As shown in FIG. 3, FIG. 3 provides the preparation method of a light-emitting device having the inverted structure. In the light-emitting device having the inverted structure, the first electrode is the cathode, and the second electrode is the anode. The light-emitting device having the inverted structure includes the cathode, a functional layer and the anode from bottom to top. The specific steps of the preparation method which an embodiment of the present disclosure provided, including:
S100: preparing the solution of the material of the functional layer on the cathode, performing the first thermal annealing treatment to form a functional layer, and then, performing the second thermal annealing treatment to the functional layer; and
S200: preparing the anode on the functional layer, to obtain the light-emitting device.

In an embodiment of the present disclosure, a total of two thermal annealing treatments are performed. The first thermal annealing treatment may remove a solvent in the solution of the material of the functional layer material, that is, the functional layer is cured from a wet film to a dry film, and the second thermal annealing treatment may remove an internal stress existing in the functional layer after the first thermal annealing treatment, thereby alleviating the problem of a functional layer being prone to cracking, and improving the performance of the light-emitting device.

As an exemplary embodiment, in an embodiment, an annealing temperature of the first thermal annealing treatment is less than 120° C. (Celsius), for example, 60° C., 70° C., 80° C., 90° C., 100° C., 110° C., 120° C., and the like. When the temperature is too low, a residual solvent will not be effectively removed. When the temperature is too high, a structure of the light-emitting layer of the light-emitting device will be easily destroyed, and a photoelectric performance of the light-emitting device will be affected.

As an exemplary embodiment, in an embodiment, an annealing time of the first thermal annealing treatment ranges from 10 min to 30 min (minutes), for example, 10 min, 12 min, 15 min, 18 min, 20 min, 22 min, 25 min, 27 min, 30 min, and the like, or other unlisted values between 10 min and 30 min. When the time is too short, the residual solvent will not be effectively removed. When the time is too long, the structure of the light-emitting layer of the light-emitting device will be easily destroyed, and the photoelectric performance of the light-emitting device will be affected.

In some embodiments, in the second thermal annealing treatment the present disclosure provided, a thermal annealing temperature is sub-high temperature, and the temperature in this range may avoid the influence of heating on the light-emitting device to the greatest extent on the basis of removing the stress of the functional layer. In some embodiments, the heating temperature of the second thermal annealing process ranges from 60° C. to 120° C., for example, 60° C., 70° C., 80° C., 90° C., 100° C., 110° C., 120° C., or other unlisted value between 60° C. and 120° C. When the temperature is too low, an effect of stress relief is not good. When the temperature is too high, it is easy to destroy the structure of the light-emitting layer of the light-emitting device and affect the photoelectric performance of the light-emitting device.

As an exemplary embodiment, in an embodiment, a thermal annealing time of the second thermal annealing treatment ranges from 5 min to 10 min, for example, 5 min, 6 min, 7 min, 8 min, 9 min, 10 min, and the like, or other unlisted values between 5 min and 10 min. When the time is too short, the effect of stress relief is not good. When the time is too long, it will affect an efficiency of production.

In some embodiments, in the step S10 or S100, the solution of the material of the functional layer may be disposed above the anode or the cathode in particular by a spin coating method. The spin coating method has the advantages of mild process conditions, a simple operation, an energy saving and an environmental protection, and the advantages of a high carrier mobility and a precise thickness for the light-emitting device preparation method. In a specific embodiment of the present disclosure, when using the spin coating method, it is necessary to configure the solution of the material of each of functional layers first, then place a film to be spin-coated on a spin coating instrument, and add the prepared solution to the top of the spin coating instrument by droplets, and perform spin coating at a preset speed. After the solution is uniformly coated, the first thermal annealing treatment and the second heating annealing treatment may be carried out.

In some embodiments, a number of functional layers are two or more layers, and the preparation method of the light-emitting device having the positive structure, including:
preparing two or more layers of solutions of the material of the functional layer on the anode, after at least any one layer of solutions of the material of the functional layer are subjected to the first thermal annealing treatment to form the film, any one functional layer is subjected to the second thermal annealing treatment; and
preparing the cathode on the functional layer which is furthest from the anode, to obtain the light-emitting device.

Alternatively, in some embodiments, the number of functional layers are two or more layers, and the method of preparing the light-emitting device having the inverted structure, including:
preparing two or more layers of solutions of the material of the functional layer on the cathode, after at least any one layer of solutions of the material of the functional layer is subjected to the first thermal annealing treatment to form the film, any one functional layer is subjected to the second thermal annealing treatment; and
preparing the anode on the functional layer which is furthest from the cathode, to obtain the light-emitting device.

In some embodiments, the number of functional layers are one or more layers, the one or more functional layers include a light-emitting layer, a hole injection layer, a hole transport layer and an electron transport layer, the hole injection layer and the hole transport layer are disposed between the light-emitting layer and the anode, the hole injection layer is disposed close to the anode, the hole transport layer is disposed close to the cathode, and the electron transport layer is disposed between the light-emitting layer and the cathode. Understandably, the above is for example only, and the functional layer in an embodiment of the present disclosure may also includes other structures known in the field. For example, at least one of the hole injection layer, the hole transport layer, the light-emitting layer and the electron transport layer are processed by the second thermal annealing treatment.

For example, in some embodiments, the method of preparing the light-emitting device having the positive structure includes:
(1) disposing the solution of the material of a hole injection layer on the anode, performing the first thermal annealing treatment and the second thermal annealing treatment to form the hole injection layer;
(2) disposing the solution of the material of a hole transport layer on the hole injection layer, performing the first thermal annealing treatment and the second thermal annealing treatment to form the hole transport layer;
(3) disposing the solution of the material of a light-emitting layer on the hole transport layer, performing the first thermal annealing treatment and the second thermal annealing treatment to form the light-emitting layer;
(4) disposing the solution of the material of a electron transport layer on the light-emitting layer, performing the first thermal annealing treatment and the second thermal annealing treatment to form the electron transport layer; and
(5) preparing the cathode on the electron transport layer.

For example, in some embodiments, the method of preparing the light-emitting device having the inverted structure includes:
(1) disposing the solution of the material of the electron transport layer on the cathode, performing the first thermal annealing treatment and the second thermal annealing treatment to form the electron transport layer;
(2) disposing the solution of the material of the light-emitting layer on the electron transport layer, performing the first thermal annealing treatment and the second thermal annealing treatment to form the light-emitting layer;
(3) disposing the solution of the material of the hole transport layer on the light-emitting layer, performing the first thermal annealing treatment and the second thermal annealing treatment to form the hole transport layer;
(4) disposing the solution of the material of the hole injection layer on the hole transport layer, performing the first thermal annealing treatment and the second thermal annealing treatment to form the hole injection layer; and
(5) preparing the anode on the hole injection layer.

The functional layers in the above-mentioned positive structure light-emitting device or inverted structure light-emitting device are subjected to the second thermal annealing treatment, so that the internal stress of each of functional layers in the light-emitting device may be removed, the problem of the functional layer being prone to cracking may be improved, the performance of the light-emitting device is better, and the yield is better.

In some embodiments, after the second thermal annealing treatment, a functional layer is cooled with a first solvent by coating or soaking, and then a next layer is disposed. Thus, by cooling each of functional layers with the first solvent, the purpose of rapidly reducing a temperature of each of functional layers may be achieved; in addition, rapid cooling may also play a role in enhancing carrier migration to a certain extent, which also has a positive impact on the light-emitting device.

In some embodiments, a temperature of the first solvent is less than or equal to 15° C.

In some embodiments, the first solvent is a non-polar solvent.

In some embodiments, a polarity of the first solvent is less than a polarity of a solvent in the solution of the material of each of functional layer.

In some embodiments, the number of functional layers are multiple layers, the multiple functional layers are arranged sequentially from bottom to top. A solvent in the solution of the material of each of functional layers is orthogonal, the polarity of the first solvent is the same as that of a solvent in the solution of the material of the next functional layer to be disposed. This may prevent the first solvent from damaging the functional layer to be cooled during the cooling process.

For example, taking the light-emitting device having positive structure as an example, in some embodiments, a solvent contained in the solution of the material of the hole injection layer is a second solvent, a solvent contained in the solution of the material of the hole transport layer is a third solvent, a solvent contained in the solution of the material of the light-emitting layer is a fourth solvent, a solvent contained in the solution of the material of the electron transport layer is a fifth solvent, a polarity of the second solvent is greater than or equal to a polarity of the third solvent, the polarity of the third solvent is greater than or equal to a polarity of the fourth solvent, and the polarity of the fourth solvent is greater than or equal to a polarity of the fifth solvent. In this way, the preparation of a new film layer will not affect an old film layer. In some embodiments, the first solvent is the non-polar solvent, or the polarity of the first solvent is less than the polarity of the fifth solvent. In some embodiments, the first solvent is n-octane, the second solvent is water, the third solvent is methanol, the fourth solvent is ethyl acetate, and the fifth solvent is toluene.

In other embodiments, the polarity of the first solvent is the same as that of a solvent in the solution of the material of the next functional layer to be disposed. That is to say, after the preparation of each of functional layers is completed, a solvent in a solution for preparing the next functional layer is configured to coat, so as to achieve a purpose of pre-spin coating. In the process of preparing device films by a solution method, the main factors affecting the uniformity include a uniformity of the lower layer film and a contact angle between a lower layer film material and a solvent. The process of conventional spin coating after pre-spin coating is equivalent to two spin coatings, that is, the pre-spin coating will remove part of the surface impurities of an upper film layer; Moreover, the existence of a residual solvent in the pre-spin coating will make the solution containing the same solvent have better spread during the spin coating process. In this way, the contact angle may be optimized, the shape of the functional layer film may be more uniform, and the internal stress of the light-emitting device may be further reduced.

For example, taking the light-emitting device having positive structure as an example, in some embodiments, the solvent contained in the solution of the material of the hole injection layer is the second solvent, the solvent contained in the solution of the material of the hole transport layer is the third solvent, the solvent contained in the solution of the material of the light-emitting layer is the fourth solvent, the solvent contained in the solution of the material of the electron transport layer is the fifth solvent, the polarity of the second solvent is greater than or equal to the polarity of the third solvent, the polarity of the third solvent is greater than or equal to the polarity of the fourth solvent, and the polarity of the fourth solvent is greater than or equal to the polarity of the fifth solvent. In the second thermal annealing treatment of the hole injection layer, the first solvent is same as the third solvent; and in the second thermal annealing treatment of the hole transport layer, the first solvent is same as the fourth solvent; and in the second thermal annealing treatment of the light-emitting layer, the first solvent is same as the fifth solvent. In some embodiments, the second solvent is water, the third solvent is methanol, the fourth solvent is ethyl acetate, and the fifth solvent is toluene.

In some embodiments of the present disclosure, the material of each of functional layers is a material known in the field for the corresponding functional layer. For example:

The material of the anode is selected from but not limited to: ITO (indium tin oxide).

A material of the light-emitting layer is a direct bandgap compound semiconductor having light-emitting ability, selected from but not limited to one or more of a group II-VI compound, a group III-V compound, a group II-V compound, a group III-VI compound, a group IV-VI compound, a group I-III-VI compound, a group II-IV-VI compound, and a group IV elementary substance. Specifically, the semiconductor material used in the light-emitting layer is selected from, but is not limited to, nanocrystals of II-VI semiconductors, such as CdS, CdSe, CdTe, ZnS, ZnSe, ZnTe, HgS, HgSe, HgTe, PbS, PbSe, PbTe, and other binary, ternary, and quaternary II-VI compounds; nanocrystals of III-V semiconductors, such as GaP, GaAs, InP, InAs, and other binary, ternary, and quaternary III-V compounds; the semiconductor material used in the light-emitting layer may also be selected from, but is not limited to, the group II-V compound, the group III-VI compound, the group IV-VI compound, the group I-III-VI compound, the group II-IV-VI compound, the group IV elemental substance, and the like. Wherein, the quantum dot light-emitting layer material may also be a doped inorganic perovskite type semiconductors, a undoped inorganic perovskite type semiconductor, and/or an organic-inorganic hybrid perovskite type semiconductor. specifically, a general structure formula of the inorganic perovskite type semiconductors is AMX₃. wherein A is C_{S}⁺; M is a divalent metal cation, selected from but not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; X is a halogen anion selected from but not limited to Cl⁻, Br⁻, and I⁻. A general structure formula of the organic-inorganic hybrid perovskite type semiconductor is BMX₃, wherein B is an organic amine cation selected from but not limited to CH₃(CH₂)ₙ₋₂NH₃⁺ (n≥2) or NH₃(CH₂)ₙNH₃²⁺ (n≥2). When n=2, an inorganic metal halide octahedron MX₆⁴⁻ is connected by a method of co-topping, a metal cation M locates in a body center of a halogen octahedron, and an organic amine cation B is filled in a gap in between the octahedron to form an three-dimensional structure extending infinitely. when n>2, an inorganic metal halide octahedron MX₆⁴⁻ connected by the method of co-topping extends in a two-dimensional direction to form a layered structure, with an organic amine cation bilayer (protonated monoamine) or an organic amine cation monolayer (protonated diamine) inserted between the layers, a plurality of organic layers and a plurality of inorganic layers overlap each other and form a stable two-dimensional layered structure; M is a divalent metal cation which may be selected from, but not limited to, Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺; X is a halogen anion which may be selected from, but not limited to, Cl⁻, Br⁻, and I⁻.

The material of the hole injection layer is selected from, but is not limited to, one or more of PEDOT:PSS(Poly (3,4-ethylene dioxythiophene)/polystyrene sulfonate), CuPc, F4-TCNQ, HATCN, a transition metal oxide and a transition metal chalcogenides.

The material of the hole transport layer is selected from, but is not limited to, one or more of poly(9,9-dioctylfluorene-co-N-(4-butylphenyl)diphenylamine), poly(N-vinylcarbazole), poly[N,N′-bis(4-butylphenyl)-N,N′-bisphenylbenzidine],Poly[(9,9-dioctylfluorenyl-2, 7-diyl)-co-(N,N′-diphenyl)-N,N′di(p-butyl-oxy-phenyl)-1,4-diaMinobenzene), 4,4′,4″-Tris(carbazol-9-yl)-triphenylamine, 4,4′-Di(9H-carbazol-9-yl)-1,1′-biphenyl, N,N′-bis(3-methylphenyl)-N,N′-diphenyl-benzidine, N,N′-Bis(1-naphthalenyl)-N,N′-bisphenyl-(1,1′-biphenyl)-4,4′-diamine, graphene and C60.

The material of the electron transport layer is selected from, but is not limited to, one or more of ZnO, TiO₂, SnO₂, Ta₂O₃, ZrO₂, NiO, TiLiO, ZnAlO, ZnMgO, ZnSnO, ZnLiO, and InSnO.

A material of the cathode is selected from, but is not limited to, one or more of a metal material, a carbon material, and a metal oxide. Wherein, the metal material includes one or more of Al (aluminum), Ag (silver), Cu (copper), Mo (molybdenum), Au (gold), Ba (barium), Ca (calcium), and Mg (magnesium). A material of the carbon includes one or more of a graphite, a carbon nanotube, a graphene and a carbon fiber. The metal oxide may be a doped or undoped metal oxide, in an embodiment, the metal oxide may including one or more of ITO, FTO, ATO, AZO, GZO, IZO, MZO, and AMO, the metal oxide may also be a composite electrode with a metal sandwiched between doped or undoped transparent metal oxides, wherein the composite electrode includes one or more of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, and ZnS/Al/ZnS. Wherein “/” denotes a laminated structure, for example, AZO/Ag/AZO denotes a composite electrode having a laminated structure formed by sequentially stacking an AZO layer, an Ag layer, and an AZO layer.

Based on the same application concept, the present disclosure also provides a light-emitting device. The light-emitting device is made by the method of the light-emitting device described in any of the above embodiments.

FIG. 4 shows a schematic diagram of the light-emitting device 10 having the positive structure according to an embodiment of the present disclosure. As shown in FIG. 4, the light-emitting device 10 having the positive structure includes a substrate 1, the anode 2 provided on the surface of the substrate 1, the hole injection layer 3 provided on the surface of the anode 2, the hole transport layer 4 provided on the surface of the hole injection layer 3, the light-emitting layer 5 provided on the surface of the hole transport layer 4, the electron transport layer 6 provided on the surface of the light-emitting layer 5, and the cathode 7 provided on the surface of the electron transport layer 6.

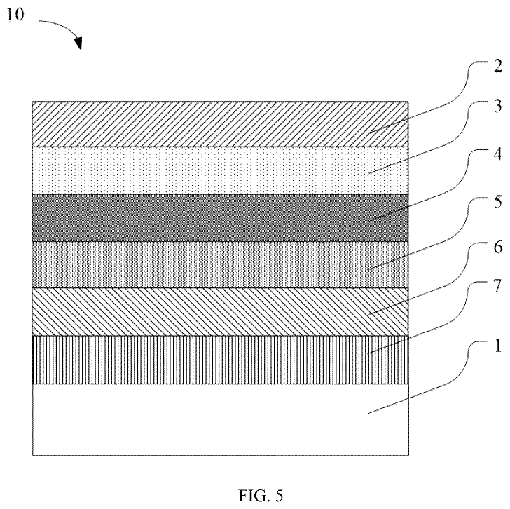

FIG. 5 shows a schematic diagram of the light-emitting device 10 having the inverted structure according to an embodiment of the present disclosure. As shown in FIG. 5, the light-emitting device 10 having the inverted structure includes a substrate 1, the cathode 7 provided on the surface of the substrate 1, the electron transport layer 6 provided on the surface of the cathode 7, the light-emitting layer 5 provided on the surface of the electron transport layer 6, the hole transport layer 4 provided on the surface of the light-emitting layer 5, the hole injection layer 3 provided on the surface of the hole transport layer 4, and the anode 2 provided on the surface of the hole injection layer 3.

On the basis of the above embodiments, the present disclosure also provides a display apparatus, the display apparatus includes the light-emitting device described in the above embodiments. A structure, an implementation principle, and an effect of the light-emitting device are similar to the light-emitting device described in the above embodiment, and details are not repeated herein.

Optionally, the display apparatus may be a lighting fixture and a backlight, or any product or component with a display function such as a mobile phone, a tablet computer, a television, a monitor, a notebook computer, a digital photo frame, a navigator, and the like.

It should be noted that the drawings of embodiments of the present disclosure only relate to the structures involved in embodiments of the present disclosure, and other structures may refer to common designs.

The following content will specifically illustrate the present disclosure through examples. The following examples are only some examples of the present disclosure and do not limit the present disclosure.

### EXAMPLE 1

Example 1 provides the light-emitting device and the method of preparing the light-emitting device. The method specifically includes:
(1) spin-coating a solution of PEDOT: PSS-water (a concentration of PEDOT: PSS is 10 mg/mL) on ITO substrates, at a rotational speed of 5000 rpm, with the spin-coating time 30 s, and then, heating for 15 min at a temperature of 100° C., and standing to cool for 5 min;
(2) performing an heating treatment to the solution of PEDOT: PSS-water at 120° C. for 5 minutes, after the heating treatment, coating n-octane and rotating at 1500 rpm to obtain the hole injection layer;
(3) spin-coating a solution of TFB-methanol (a concentration of TFB is 8 mg/mL) at a rotational speed of 3000 rpm, with the spin-coating time 30 s, and then, heating for 10 min at a temperature of 80° C., and standing to cool for 5 min;
(4) performing an heating treatment to the solution of TFB-methanol at 120° C. for 5 min, after the heating treatment, coating n-octane and rotating at 1500 rpm to obtain the hole transport layer;
(5) spin-coating a solution of quantum dots-ethyl acetate (a concentration of quantum dots is 20 mg/mL) at a rotational speed of 2000 rpm, with the spin-coating time 30 s, and then, heating for 10 min at a temperature of 80° C., and standing to cool for 5 min;
(6) performing an heating treatment to a solution of quantum dots-ethyl acetate at 120° C. for 5 min, after the heating treatment, coating n-octane and rotating at 1500 rpm to obtain the light-emitting layer;
(7) spin-coating a solution of ZnO-toluene (a concentration of ZnO is 30 mg/mL) at a rotational speed of 2000 rpm, with the spin-coating time 30 s, and then, heating for 20 min at a temperature of 80° C., and standing to cool for 5 min;
(8) performing an heating treatment to the solution of ZnO-toluene at 120° C. for 5 min, after the heating treatment, coating n-octane and rotating at 1500 rpm to obtain the electron transport layer;
(9) Ag layer was evaporated by thermal evaporation with vacuum degree not higher than 3×10⁻⁴ Pa, speed at 1 Å/s, time at 200 seconds, and thickness 20 nm. A top-emitting positive type light-emitting device is obtained, and the light-emitting device is encapsulated.

### EXAMPLE 2

Example 2 provides the light-emitting device and the method of preparing a light-emitting device. The method specifically includes:
(1) Spin-coating the solution of PEDOT: PSS-water (a concentration of PEDOT: PSS is 10 mg/mL) on ITO substrates, at a rotational speed of 5000 rpm, with the spin-coating time 30 s, and then, heating for 15 min at a temperature of 100° C., and standing to cool for 5 min;
(2) performing an heating treatment to the solution of PEDOT: PSS-water at 120° C. for 5 min, after the heating treatment, coating methanol and rotating at 1500 rpm to obtain the hole injection layer;
(3) spin-coating the solution of TFB-methanol (a concentration of TFB is 8 mg/mL) at a rotational speed of 3000 rpm, with the spin-coating time 30 s, and then, heating for 10 min at a temperature of 80° C., and standing to cool for 5 min;
(4) performing an heating treatment to the solution of TFB-methanol at 120° C. for 5 min, after the heating treatment, coating ethyl acetate and rotating at 1500 rpm to obtain the hole transport layer;
(5) spin-coating the solution of quantum dots-ethyl acetate (a concentration of quantum dots is 20 mg/mL) at a rotational speed of 2000 rpm, with the spin-coating time 30 s, and then, heating for 10 min at a temperature of 80° C., and standing to cool for 5 min;
(6) performing an heating treatment to the solution of quantum dots-ethyl acetate at 120° C. for 5 min, after the heating treatment, coating toluene and rotating at 1500 rpm to obtain the light-emitting layer;
(7) spin-coating the solution of ZnO-toluene (a concentration of ZnO is 30 mg/mL) at a rotational speed of 2000 rpm, with the spin-coating time 30 s, and then, heating for 20 min at a temperature of 80° C., and standing to cool for 5 min;
(8) performing an heating treatment to the solution of ZnO-toluene at 120° C. for 5 minutes, after the heating treatment, coating n-octane and rotating at 1500 rpm to obtain the electron transport layer;
(9) Ag layer was evaporated by thermal evaporation with vacuum degree not higher than 3×10⁻⁴ Pa, speed at 1 Å/s, time at 200 seconds, and thickness 20 nm. A top-emitting positive type light-emitting device is obtained, and the light-emitting device is encapsulated.

### Comparative Example 1

Comparative Example 1 provides the light-emitting device and the method of preparing the light-emitting device. The method specifically includes:
(1) Spin-coating an solution of PEDOT: PSS on ITO substrates, at a rotational speed of 5000 rpm, with the spin-coating time 30 s, and then, heating for 15 min at a temperature of 150° C., and standing to cool for 5 min, to obtain the hole injection layer;
(2) spin-coating a solution of TFB (a concentration of TFB is 8 mg/mL) at a rotational speed of 3000 rpm, with the spin-coating time 30 s, and then, heating for 10 min at a temperature of 80° C., and standing to cool for 5 min, to obtain the hole transport layer;
(3) spin-coating a solution of quantum dots (a concentration of quantum dots is 20 mg/mL) at a rotational speed of 2000 rpm, with the spin-coating time 30 s, and then, heating for 10 min at a temperature of 80° C., and standing to cool for 5 min, to obtain the light-emitting layer;
(4) spin-coating a solution of ZnO (a concentration of ZnO is 30 mg/mL) at a rotational speed of 2000 rpm, with the spin-coating time 30 s, and then, heating for 20 min at a temperature of 80° C., and standing to cool for 5 min, to obtain the electron transport layer;
(5) Ag layer was evaporated by thermal evaporation with vacuum degree not higher than 3×10⁻⁴ Pa, speed at 1 Å/s, time at 200 seconds, and thickness 20 nm. A top-emitting positive type light-emitting device is obtained, and the light-emitting device is encapsulated.

### Comparative Example 2

Comparative Example 2 provides the light-emitting device and the method of preparing the light-emitting device. The method specifically includes:
(1) spin-coating an solution of PEDOT: PSS on ITO substrates, at a rotational speed of 5000 rpm, with the spin-coating time 30 s, and then, heating for 15 min at a temperature of 100° C., and standing to cool for 5 min;
(2) performing an heating treatment to the solution of the material of PEDOT: PSS at 120° C. for 5 min, to obtain the hole injection layer;
(3) spin-coating a solution of TFB (a concentration of TFB is 8 mg/mL) at a rotational speed of 3000 rpm, with the spin-coating time 30 s, and then, heating for 10 min at a temperature of 80° C., and standing to cool for 5 min;
(4) performing an heating treatment to TFB at 120° C. for 5 min, to obtain the hole transport layer;
(5) spin-coating a solution of quantum dots (a concentration of quantum dots is 20 mg/mL) at a rotational speed of 2000 rpm, with the spin-coating time 30 s, and then, heating for 10 min at a temperature of 80° C., and standing to cool for 5 min;
(6) performing an heating treatment to quantum dots at 120° C. for 5 min, to obtain the light-emitting layer;
(7) spin-coating a solution of ZnO (a concentration of ZnO is 30 mg/mL) at a rotational speed of 2000 rpm, with the spin-coating time 30 s, and then, heating for 20 min at a temperature of 80° C., and standing to cool for 5 min;
(8) performing an heating treatment to the solution of the material of ZnO at 120° C. for 5 min, to obtain the electron transport layer;
(9) Ag layer was evaporated by thermal evaporation with vacuum degree not higher than 3×10⁻⁴ Pa, speed at 1 Å/s, time at 200 seconds, and thickness 20 nm. A top-emitting positive type light-emitting device is obtained, and the light-emitting device is encapsulated.

### Validation Example

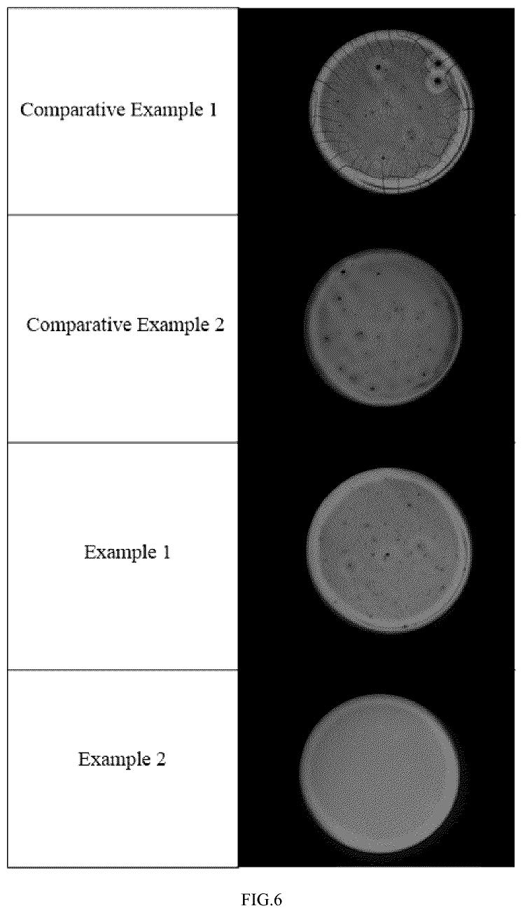

In an embodiment of the present application, heat treatment and annealing treatment are performed on each of functional layers, and the heat treatment and annealing treatment may affect the electrical performance of the light-emitting device. In order to illustrate this effect, the present disclosure also provides a verification example. Referring to a method known in the field, the JVL data of the light-emitting device prepared by Examples 1 to 2 and Comparative Examples 1 to 2 are tested respectively, the electrical performance of the light-emitting device is determined, and the light-emitting device electroluminescence topography is photographed (the light-emitting layer topography is photographed using an optical microscope), and the results are shown in Table 1 and FIG. 6.

TABLE 1

| | L | T95 | T95-1 Knit | C.E | C.E-1000 nit |
|---|---|---|---|---|---|
| | (cd/m²) | (h) | (h) | (cd/A) | (cd/A) |
| Comparative | 57140 | 8.36 | 8110 | 89.71 | 30.9 |
| Example 1 | | | | | |
| Comparative | 58550 | 13.11 | 13256 | 91.92 | 74.9 |
| Example 2 | | | | | |
| Example 1 | 65130 | 13.98 | 16941 | 102.25 | 95.3 |
| Example 2 | 71370 | 14.37 | 20344 | 112.05 | 104.8 |

Note: L means the luminance of the light-emitting device. Under the same current, the higher the luminance of the light-emitting device, the better the efficiency of the light-emitting device. T95 indicates the time it takes for the light-emitting device luminance to decay from 100% to 95%, under the same current, the longer the T95 time the light-emitting device taken, the better the performance and the better the stability of the light-emitting device. T95-1K refers to when the light-emitting device luminance is 1000 nit, the time it takes for the luminance to decay from 100% to 95%, this value is calculated from the values of L and T95. C.E refers to the current efficiency of the light-emitting device. Under the premise that the area of the luminescent region and the driving current are consistent, the higher the C.E, the better the performance of the light-emitting device. C.E-1000 nit indicates the current efficiency of the light-emitting device at 1000 nit brightness. Under the premise that the luminous area and the driving current are consistent, the higher the C.E-1000 nit, the better the light-emitting device performance.

As shown in Table 1, for the L value, T95 value, T95-1K nit value, C.E value, and C.E-1000 nit value of each of the comparisons and embodiments, the data of Example 2 is greater than that of Example 1, the data of Example 1 is greater than that of Comparative Example 2, and the data of Comparative Example 2 is greater than that of Comparative Example 1.

As shown in FIG. 6, the light-emitting layer of Comparative Example 1 has a thin film cracking and a non-uniform morphology. Although the light-emitting layer of Comparative Example 2 avoids cracking, its light emitting is uneven. Although the light-emitting layer of Example 1 avoids cracking, its light emitting is uneven, and its morphology is slightly better than that of Comparative Example 2. The light-emitting layer of Example 2 not only avoids cracking, but also has a good morphology.

In summary, comparing the light-emitting device performance and morphology of Comparative Example 1 with that of Comparative Example 2, Comparative Example 2 is better than Comparative Example 1. It shows that the secondary annealing of the functional layer will reduce the stress of the light-emitting device, improve the performance of the light-emitting device and avoid the cracking of the functional layer to a certain extent.

Comparing the light-emitting device performance and morphology of Comparative Example 2 with that of Example 1, Example 1 is better than Comparative Example 2. The results show that using the solvent to quickly cool down the functional layer of the light-emitting device will reduce the stress of the light-emitting device, improve the performance of the light-emitting device, and may also avoid the cracking of the functional layer, and improve the yield of the light-emitting device.

Comparing the light-emitting device performance and morphology of the Example 2 with that of the Example 1, the Example 2 is better than the Example 1. In Example 1, the same solvent was used for treatment after the second thermal annealing, while in Example 2, the same solvent (i.e. an orthogonal solvent) was used as the next layer, indicating that cooling the functional layer of the light-emitting device by using the orthogonal solvent will further reduce the stress, improve the performance of the light-emitting device, make the film layer of the functional layer more uniform, avoid the cracking of the functional layer, and improve the yield of the light-emitting device. This is because the stress reduction of the functional layer will reduce the impact of the light-emitting device short circuit on the electrical performance of the light-emitting device, especially on the measured working life of the light-emitting device. The short circuit of the light-emitting device is caused by the direct contact between the functional layer located above the cracked functional layer and the functional layer located below it. When the electrical performance of the light-emitting device decreases, the T95 value of the light-emitting device also decreases significantly.

The above embodiments of the present disclosure provide a light-emitting device preparation method, a light-emitting device, and a display apparatus, and describe them in detail. Specific examples are used to describe the principles and implementations of the present disclosure. The description of the above embodiments is merely intended to help understand the technical solutions and the core idea of the present disclosure. It is to be understood by those of ordinary skill in the art that modifications may still be made to the technical solutions described in the foregoing embodiments, or equivalent substitutions may be made to some of the technical features therein. These modifications or substitutions do not depart the essence of the corresponding technical solutions from the scope of the embodiments of the present disclosure.

1. A method of preparing a light-emitting device, comprising:
preparing one or more functional layers on a first electrode; and
preparing a second electrode on the one or more functional layers;
wherein, at least one of the one or more functional layers are obtained by subjecting a solution of a material of a corresponding functional layer to a first thermal annealing treatment and then a second thermal annealing treatment.

2. The method according to claim 1, wherein a thermal annealing temperature of the second thermal annealing treatment ranges from 60° C. to 120° C.

3. The method according to any claim 1, wherein a thermal annealing time of the second thermal annealing treatment ranges from 5 min to 10 min.

4. The method according to claim 1, wherein after the second thermal annealing treatment, a functional layer is cooled with a first solvent by coating or soaking, and then a next layer is disposed.

5. The method according to claim 4, wherein a polarity of the first solvent is less than a polarity of a solvent in a solution of a material of each of functional layers.

6. The method according to claim 4, wherein the first solvent is a non-polar solvent.

7. The method according to claim 4, wherein the solvent in the solution of the material of each of functional layers is orthogonal, and the polarity of the first solvent is the same as that of the solvent in the solution of the material of a next functional layer to be disposed.

8. The method according to claim 4, wherein a temperature of the first solvent is less than or equal to 15° C.

9. The method according to claim 1, wherein the one or more functional layers comprise a light-emitting layer, a hole injection layer, a hole transport layer and an electron transport layer, the hole injection layer and the hole transport layer are disposed between the light-emitting layer and the first electrode, the hole injection layer is disposed close to the first electrode, the hole transport layer is disposed close to the second electrode, and the electron transport layer is disposed between the light-emitting layer and the second electrode, wherein one or more layers of the hole injection layer, the hole transport layer, the light-emitting layer and the electron transport layer are processed by the second thermal annealing treatment.

10. The method according to claim 9, wherein the method comprises:
disposing the solution of the material of a hole injection layer on the first electrode, performing the first thermal annealing treatment and the second thermal annealing treatment to form the hole injection layer;
disposing the solution of the material of a hole transport layer on the hole injection layer, performing the first thermal annealing treatment and the second thermal annealing treatment to form the hole transport layer;
disposing the solution of the material of a light-emitting layer on the hole transport layer, performing the first thermal annealing treatment and the second thermal annealing treatment to form the light-emitting layer;
disposing the solution of the material of a electron transport layer on the light-emitting layer, performing the first thermal annealing treatment and the second thermal annealing treatment to form the electron transport layer; and
preparing the second electrode on the electron transport layer.

11. The method according to claim 9, wherein the method comprises:
disposing the solution of the material of the electron transport layer on the first electrode, performing the first thermal annealing treatment and the second thermal annealing treatment to form the electron transport layer;
disposing the solution of the material of the light-emitting layer on the electron transport layer, performing the first thermal annealing treatment and the second thermal annealing treatment to form the light-emitting layer;
disposing the solution of the material of the hole transport layer on the light-emitting layer, performing the first thermal annealing treatment and the second thermal annealing treatment to form the hole transport layer;
disposing the solution of the material of the hole injection layer on the hole transport layer, performing the first thermal annealing treatment and the second thermal annealing treatment to form the hole injection layer; and
preparing the second electrode on the hole injection layer.

12. The method according to claim 9, wherein in the second thermal annealing treatment, the functional layer is cooled with the first solvent by coating or soaking, and then the next layer is disposed; wherein a solvent contained in the solution of the material of the hole injection layer is a second solvent, a solvent contained in the solution of the material of the hole transport layer is a third solvent, a solvent contained in the solution of the material of the light-emitting layer is a fourth solvent, a solvent contained in the solution of the material of the electron transport layer is a fifth solvent, a polarity of the second solvent is greater than or equal to a polarity of the third solvent, the polarity of the third solvent is greater than or equal to a polarity of the fourth solvent, and the polarity of the fourth solvent is greater than or equal to a polarity of the fifth solvent;
wherein the polarity of the first solvent is less than a polarity of the fifth solvent.

13. The method according to claim 9, wherein in the second thermal annealing treatment, the functional layer is cooled with the first solvent by coating or soaking, and then the next layer is disposed; wherein the solvent contained in the solution of the material of the hole injection layer is the second solvent, the solvent contained in the solution of the material of the hole transport layer is the third solvent, the solvent contained in the solution of the material of the light-emitting layer is the fourth solvent, the solvent contained in the solution of the material of the electron transport layer is the fifth solvent, the polarity of the second solvent is greater than or equal to the polarity of the third solvent, the polarity of the third solvent is greater than or equal to the polarity of the fourth solvent, and the polarity of the fourth solvent is greater than or equal to the polarity of the fifth solvent;
wherein the first solvent is the non-polar solvent.

14. The method according to claim 9, wherein in the second thermal annealing treatment, the functional layer is cooled with the first solvent by coating or soaking, and then the next layer is disposed; wherein the solvent contained in the solution of the material of the hole injection layer is the second solvent, the solvent contained in the solution of the material of the hole transport layer is the third solvent, the solvent contained in the solution of the material of the light-emitting layer is the fourth solvent, the solvent contained in the solution of the material of the electron transport layer is the fifth solvent, the polarity of the second solvent is greater than or equal to the polarity of the third solvent, the polarity of the third solvent is greater than or equal to the polarity of the fourth solvent, and the polarity of the fourth solvent is greater than or equal to the polarity of the fifth solvent;
wherein in the second thermal annealing treatment of the hole injection layer, the first solvent is same as the third solvent; and in the second thermal annealing treatment of the hole transport layer, the first solvent is same as the fourth solvent; and in the second thermal annealing treatment of the light-emitting layer, the first solvent is same as the fifth solvent.

15. The method according to claim 9, wherein the temperature of the first solvent is less than or equal to 15° C.

16. The method according to claim 9, wherein a thermal annealing temperature of the first thermal annealing treatment ranges from 60° C. to 120° C.

17. The method according to claim 9, wherein a thermal annealing time of the first thermal annealing treatment ranges from 10 min to 30 min.

18. The method according to claim 9, wherein the material of the light-emitting layer comprises a direct bandgap compound semiconductor or a perovskite type semiconductor, the direct bandgap compound semiconductor comprises one or more of a group II-VI compound, a group III-V compound, a group II-V compound, a group III-VI compound, a group IV-VI compound, a group I-III-VI compound, a group II-IV-VI compound, and a group IV elementary substance, the group II-VI compound is selected from one or more of CdSe, CdS, CdTe, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, and CdZnSTe; the group III-V compound is selected from one or more of InP, InAs, GaP, GaAs, GaSb, AlN, AlP, InAsP, InNP, InNSb, GaAlNP, and InAlNP; the group I-III-VI compound is selected from one or more of CuInS₂, CuInSe₂, and AgInS₂; the perovskite type semiconductor comprises one or more of a doped inorganic perovskite type semiconductors, a undoped inorganic perovskite type semiconductors, and an organic-inorganic hybrid perovskite type semiconductor, a general structure formula of the inorganic perovskite type semiconductors is AMX₃, a general structure formula of the organic-inorganic hybrid perovskite type semiconductor is BMX₃, wherein A is C_{S}⁺, B is an organic amine cation, the organic amine cation comprises CH₃(CH₂)ₙ₋₂NH₃⁺ (n≥2) or NH₃(CH₂)ₙNH₃²⁺ (n≥2), M is a divalent metal cation, the divalent metal cation comprises one of Pb²⁺, Sn²⁺, Cu²⁺, Ni²⁺, Cd²⁺, Cr²⁺, Mn²⁺, Co²⁺, Fe²⁺, Ge²⁺, Yb²⁺, and Eu²⁺, X is a halogen anion, the halogen anion comprises one of Cl⁻, Br⁻, and I⁻;
the material of the hole injection layer comprises one or more of PEDOT:PSS, CuPc, F4-TCNQ, HATCN, a transition metal oxide, and a transition metal chalcogenides;
the material of the hole transport layer comprises one or more of poly(9,9-dioctylfluorene-co-N-(4-butylphenyl)diphenylamine), poly(N-vinylcarbazole), poly[N,N′-bis(4-butylphenyl)-N,N′-bisphenylbenzidine],Poly[(9,9-dioctylfluorenyl-2,7-diyl)-co-(N,N′-diphenyl)-N,N′di(p-butyl-oxy-phenyl)-1,4-diaMinobenzene) 4,4′,4″-Tris(carbazol-9-yl)-triphenylamine, 4,4′-Di(9H-carbazol-9-yl)-1,1′-biphenyl, N,N′-bis(3-methylphenyl)-N,N′-diphenyl-benzidine, N,N′-Bis(1-naphthalenyl)-N,N′-bisphenyl-(1,1′-biphenyl)-4,4′-diamine, graphene, and C60; and
the material of the electron transport layer comprises one or more of ZnO, TiO₂, SnO₂, Ta₂O₃, ZrO₂, NiO, TiLiO, ZnAlO, ZnMgO, ZnSnO, ZnLiO, and InSnO.

19. A light-emitting device prepared by a method of preparing a light-emitting device, wherein the method comprises:
preparing one or more functional layers on a first electrode; and
preparing a second electrode on the one or more functional layers;
wherein, at least one of the one or more functional layers are obtained by subjecting a solution of a material of a corresponding functional layer to a first thermal annealing treatment and then a second thermal annealing treatment.

20. A display apparatus comprising the light-emitting device prepared by a method of preparing a light-emitting device, wherein the method comprises:
preparing one or more functional layers on a first electrode; and
preparing a second electrode on the one or more functional layers;
wherein, at least one of the one or more functional layers are obtained by subjecting a solution of a material of a corresponding functional layer to a first thermal annealing treatment and then a second thermal annealing treatment.
